(19) United States
(12) Patent Application Publication
(10) Pub. No.: US 2026/0059751 A1
(43) Pub. Date: Feb. 26, 2026

(54) SEMICONDUCTOR DEVICE AND METHOD OF MANUFACTURING SAME

(71) Applicant: Kioxia Corporation, Tokyo (JP)

(72) Inventor: Satoshi NAKAOKA, Yokkaichi Mie (JP)

(73) Assignee: Kioxia Corporation, Tokyo (JP)

(21) Appl. No.: 19/047,733

(22) Filed: Feb. 7, 2025

(30) Foreign Application Priority Data
Aug. 22, 2024 (JP) 2024-141169

(51) Int. Cl. H10B 43/27; H10B 41/10; H10B 41/27; H10B 41/35; H10B 43/10; H10B 43/35

(52) U.S. Cl. CPC H10B 43/27; H10B 41/10; H10B 41/27; H10B 41/35; H10B 43/10; H10B 43/35

(57) ABSTRACT

In one embodiment, a semiconductor device includes a stacked film including a plurality of first insulators and a plurality of electrode layers that are alternately provided in a first direction, and a plurality of columnar portions extending in the first direction in the stacked film. A first columnar portion among the plurality of columnar portions includes a second insulator provided on side faces of the plurality of first insulators and the plurality of electrode layers, and including a metallic element, a third insulator provided on a side face of the second insulator, and including silicon, a charge storage layer provided on a side face of the third insulator, a fourth insulator provided on a side face of the charge storage layer, and a semiconductor layer provided on a side face of the fourth insulator.

### CROSS-REFERENCE TO RELATED APPLICATIONS

This application is based upon and claims the benefit of priority from the prior Japanese Patent Application No. 2024-141169, filed on Aug. 22, 2024, the entire contents of which are incorporated herein by reference.

### FIELD

Embodiments described herein relate to a semiconductor device and a method of manufacturing the same.

### BACKGROUND

When a three-dimensional semiconductor memory is manufactured, a plurality of electrode layers (e.g., word lines) stacked in a vertical direction are formed by, for example, a replacement step through a slit. In this case, there are problems that the slit must be formed for the replacement step, processing difficulty of the replacement step is high, and the replacement step takes a long time.

### BRIEF DESCRIPTION OF THE DRAWINGS

FIG. 1 is a cross-sectional view illustrating a structure of a semiconductor device of a first embodiment;

FIG. 2 is a plan view illustrating the structure of the semiconductor device of the first embodiment;

FIG. 3 is a perspective view illustrating the structure of the semiconductor device of the first embodiment;

FIG. 4 is a cross-sectional view illustrating the structure of the semiconductor device of the first embodiment;

FIG. 5 is a cross-sectional view illustrating the structure of the semiconductor device of the first embodiment;

FIGS. 6A to 10B are plan views and cross-sectional views which illustrate a method of manufacturing the semiconductor device of the first embodiment;

FIGS. 11A and 11B are plan views which illustrate the structure of the semiconductor device of the first embodiment, and a structure of a semiconductor device of a comparative example of the first embodiment;

FIGS. 12A and 12B are plan views which illustrate structures of semiconductor devices of first and second modifications of the first embodiment;

FIGS. 13A and 13B are a plan view and a graph for explaining dimensions of the semiconductor device of the first embodiment;

FIGS. 14A to 14C are plan views and a graph for explaining dimensions of a semiconductor device of a third modification of the first embodiment;

FIG. 15 is a cross-sectional view illustrating a structure of a semiconductor device of a fourth modification of the first embodiment;

FIGS. 16A to 16C are plan views and a graph for explaining a structure of a semiconductor device of a second embodiment;

FIGS. 17A to 17C are a cross-sectional view and plan views for explaining a structure of a semiconductor device of a third embodiment;

FIGS. 18A to 20B are cross-sectional views illustrating a method of manufacturing a semiconductor device of a fourth embodiment;

FIG. 21 is a cross-sectional view illustrating a structure of a semiconductor device of a fifth embodiment;

FIG. 22 is a plan view illustrating the structure of the semiconductor device of the fifth embodiment;

FIGS. 23A to 29B are cross-sectional views and plan views which illustrate a method of manufacturing the semiconductor device of the fifth embodiment; and

FIGS. 30A and 30B are plan views illustrating a method of manufacturing a semiconductor device of a modification of the fifth embodiment.

### DETAILED DESCRIPTION OF THE INVENTION

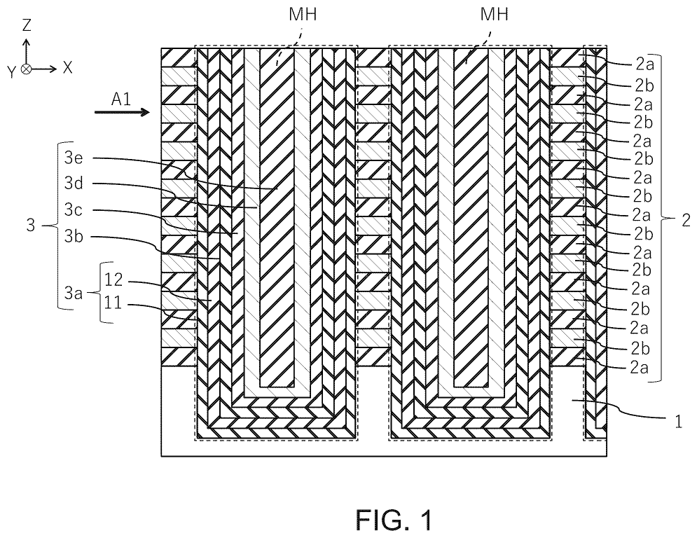

Embodiments will now be explained with reference to the accompanying drawings. In FIGS. 1 to 30B, the same reference characters will be given to the same configurations, and descriptions thereof will not be repeated.

In one embodiment, a semiconductor device includes a stacked film including a plurality of first insulators and a plurality of electrode layers that are alternately provided in a first direction, and a plurality of columnar portions extending in the first direction in the stacked film. A first columnar portion among the plurality of columnar portions includes a second insulator provided on side faces of the plurality of first insulators and the plurality of electrode layers, and including a metallic element, a third insulator provided on a side face of the second insulator, and including silicon, a charge storage layer provided on a side face of the third insulator, a fourth insulator provided on a side face of the charge storage layer, and a semiconductor layer provided on a side face of the fourth insulator.

### First Embodiment

FIG. 1 is a cross-sectional view illustrating a structure of a semiconductor device of a first embodiment. The semiconductor device of the present embodiment is a three-dimensional semiconductor memory, for example.

The semiconductor device of the present embodiment includes a substrate 1, a stacked film 2, and a plurality of columnar portions 3. The stacked film 2 includes a plurality of insulators 2a and a plurality of electrode layers 2b. Each of the columnar portions 3 includes a block insulator 3a, a charge storage layer 3b, a tunnel insulator 3c, a channel semiconductor layer 3d, and a core insulator 3e. The block insulator 3a in each of the columnar portions 3 includes an insulator 11 and an insulator 12. The insulator 2a, the insulator 11, the insulator 12, and the tunnel insulator 3c are respective examples of the first, second, third, and fourth insulators. The channel semiconductor layer 3d is an example of a semiconductor layer, and each of the columnar portions 3 is an example of a first columnar portion.

The substrate 1 is a semiconductor substrate such as a Si (silicon) substrate, for example. FIG. 1 indicates an X direction and a Y direction which are parallel with a surface of the substrate 1 and are perpendicular to each other and a Z direction which is perpendicular to the surface of the substrate 1. In the present specification, a +Z direction is dealt with as an upward direction, and a −Z direction is dealt with as a downward direction. The −Z direction may agree with a gravity direction or may not agree with the gravity direction. The Z direction is an example of a first direction.

The stacked film 2 is formed on the substrate 1. The stacked film 2 may be formed above the substrate 1 via another film (for example, an inter layer dielectric). The stacked film 2 includes the plurality of insulators 2a and the plurality of electrode layers 2b which are alternately provided in the Z direction. Each of the insulators 2a is a SiO₂ film (silicon oxide film), for example. Each of the electrode layers 2b is a metal layer such as a Mo (molybdenum) layer, for example. Each of the electrode layers 2b functions as a word line, a source-side selection line, or a drain-side selection line, for example.

FIG. 1 illustrates a plurality of memory holes MH which are formed in the stacked film 2. Each of the memory holes MH extends in the Z direction and has a circular shape in a planar view. Each of the memory holes MH of the present embodiment passes through the stacked film 2 in the Z direction and reaches the substrate 1. Each of the memory holes MH is an example of a first concave portion.

Each of the columnar portions 3 is formed in one corresponding memory hole MH. Thus, each of the columnar portions 3 extends in the Z direction and has a circular shape in the planar view. Each of the columnar portions 3 of the present embodiment passes through the stacked film 2 in the Z direction and reaches the substrate 1. Each of the columnar portions 3 includes the insulator 11, the insulator 12, the charge storage layer 3b, the tunnel insulator 3c, the channel semiconductor layer 3d, and the core insulator 3e, which are in order formed on the substrate 1, a side face of the stacked film 2, and an upper face of the substrate 1.

The insulator 11 is formed on the substrate 1, side faces of the plurality of insulators 2a and of the plurality of electrode layers 2b, and the upper face of the substrate 1. The insulator 11 is an AlOₓ film (aluminum oxide film), for example. An Al element in the insulator 11 is an example of a metallic element in a first insulator.

The insulator 12 is formed on a side face and an upper face of the insulator 11. The insulator 12 is a SiO₂ film, for example.

The charge storage layer 3b is formed on a side face and an upper face of the insulator 12. The charge storage layer 3b is an insulator such as a SiN film (silicon nitride film), for example. The charge storage layer 3b may be a semiconductor layer such as a polysilicon layer. The charge storage layer 3b of the present embodiment is capable of storing a signal charge of the three-dimensional semiconductor memory.

The tunnel insulator 3c is formed on a side face and an upper face of the charge storage layer 3b. The tunnel insulator 3c is a SiO₂ film, for example.

The channel semiconductor layer 3d is formed on a side face and an upper face of the tunnel insulator 3c. The channel semiconductor layer 3d is a polysilicon layer, for example. The channel semiconductor layer 3d of the present embodiment functions as a channel of a plurality of cell transistors (memory cells) and a plurality of selection transistors in the three-dimensional semiconductor memory.

The core insulator 3e is formed on a side face and an upper face of the channel semiconductor layer 3d. The core insulator 3e is a SiO₂ film, for example.

The insulator 11 of the present embodiment is not a portion of the stacked film 2 but a portion of the columnar portion 3 and is specifically formed on the side faces of the plurality of insulators 2a and of the plurality of electrode layers 2b. A method of forming such an insulator 11 will be described later.

Note that the semiconductor device of the present embodiment may not include the substrate 1 on a lower side of the stacked film 2. For example, in a case where the semiconductor device of the present embodiment is manufactured by pasting together two or more substrates, the semiconductor device of the present embodiment may include a substrate on an upper side of the stacked film 2 instead of including the substrate 1 on the lower side of the stacked film 2.

Each of the electrode layers 2b of the present embodiment may include a barrier metal layer and an electrode material layer. An example of such an electrode layer 2b will be described later.

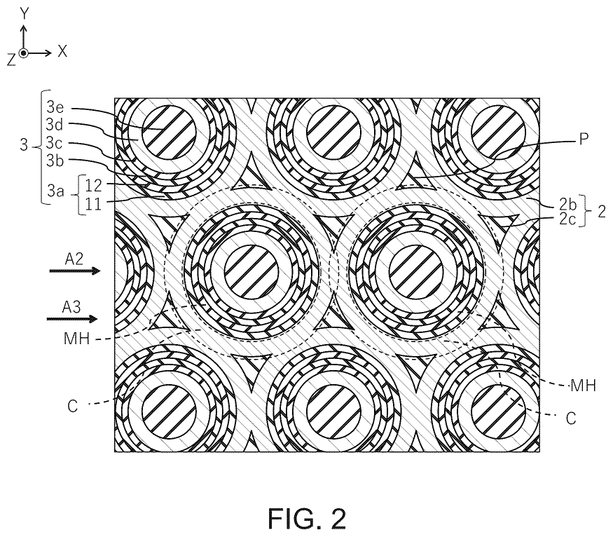

FIG. 2 is a plan view illustrating the structure of the semiconductor device of the first embodiment. FIG. 2 illustrates an XY cross section at a position of an arrow A1 indicated in FIG. 1. Meanwhile, FIG. 1 illustrates an XZ cross section at a position of an arrow A2 indicated in FIG. 2.

FIG. 2 illustrates the plurality of columnar portions 3 which are arranged in a shape of a triangular lattice in the planar view. In the present embodiment, the triangular lattice is formed with a plurality of equilateral triangles. The triangular lattice may be formed with a plurality of triangles other than the equilateral triangles and may be formed with a plurality of isosceles triangles, for example. An example of such a triangular lattice will be described later.

The stacked film 2 includes a plurality of insulators 2c in addition to the plurality of insulators 2a and the plurality of electrode layers 2b. Specifically, the stacked film 2 includes the plurality of insulators 2a and a plurality of composite layers which are alternately formed in the Z direction, and each of the plurality of composite layers includes one electrode layer 2b and one insulator 2c as illustrated in FIG. 2. Each of the insulators 2c is a SiN film, for example. Each of the insulators 2c is an example of a fifth insulator. One insulator 2c illustrated in FIG. 2 includes a plurality of portions P which are separated from each other. Each of the portions P is an example of a first portion.

One electrode layer 2b and one insulator 2c which are illustrated in FIG. 2 are provided between two insulators 2a (FIG. 1) which are adjacent to each other in the Z direction. The two insulators 2a are examples of an upper insulator and a lower insulator. One electrode layer 2b and one insulator 2c which are illustrated in FIG. 2 are respective examples of a predetermined electrode layer and a predetermined fifth insulator.

One electrode layer 2b illustrated in FIG. 2 has a shape which includes a plurality of annular portions in the planar view. The plurality of annular portions are arranged in the shape of the triangular lattice and are arranged to partially overlap with each other. Each of the annular portions is arranged to annularly surround one corresponding columnar portion 3. Each of the annular portions is an example of a surrounding portion which surrounds the columnar portion.

As described above, one insulator 2c illustrated in FIG. 2 includes the plurality of portions P which are separated from each other. The plurality of portions P are provided in one electrode layer 2b illustrated in FIG. 2. Each of the portions P is interposed among three columnar portions 3 in the planar view and is interposed among three annular portions of the electrode layers 2b in the planar view. Each of the portions P is formed on the side face of the electrode layer 2b. Each of the portions P has a shape close to a triangle in the planar view.

When the semiconductor device of the present embodiment is manufactured, a plurality of cavities C are formed around each of the memory holes MH. Each of the cavities C around each of the memory holes MH is formed between two insulators 2a (FIG. 1) which are adjacent to each other in the Z direction. FIG. 2 illustrates, by broken lines, positions of two cavities C around two memory holes MH. In FIG. 2, the two cavities C are arranged to partially overlap with each other. In one electrode layer 2b illustrated in FIG. 2, each of the annular portions is formed in one corresponding cavity C. In other words, each of the annular portions of the electrode layer 2b corresponds to a portion in one cavity C in the electrode layer 2b. Each of the cavities C is an example of a second concave portion.

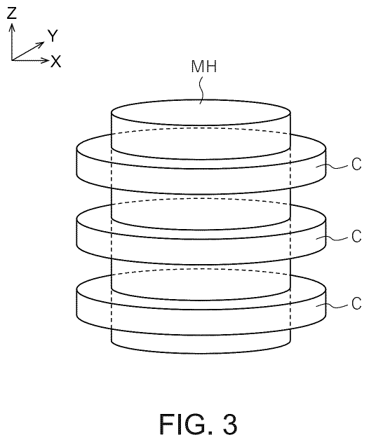

FIG. 3 is a perspective view illustrating the structure of the semiconductor device of the first embodiment.

FIG. 3 illustrates a shape of one memory hole MH and shapes of the cavities C around the memory hole MH. When the semiconductor device of the present embodiment is manufactured, as described above, the plurality of cavities C are formed around each of the memory holes MH. Each of the cavities C has a shape which annularly surrounds the memory hole MH in the planar view.

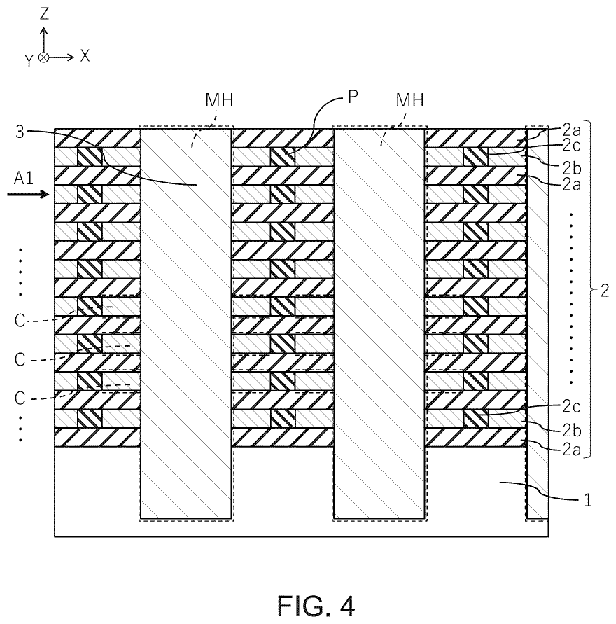

FIG. 4 is a cross-sectional view illustrating the structure of the semiconductor device of the first embodiment. FIG. 1 illustrates the XZ cross section at the position of the arrow A2 indicated in FIG. 2. Meanwhile, FIG. 4 illustrates an XZ cross section at a position of an arrow A3 indicated in FIG. 2. Note that in FIG. 4, an illustration of an internal structure of each of the columnar portions 3 is omitted (similar omission will appropriately apply to the other drawings described later).

As described above, the stacked film 2 includes the plurality of insulators 2a, the plurality of electrode layers 2b, and the plurality of insulators 2c. Specifically, the stacked film 2 includes the plurality of insulators 2a and the plurality of composite layers which are alternately formed in the Z direction, and each of the composite layers includes one electrode layer 2b and one insulator 2c as illustrated in FIG. 4. In FIG. 4, each of the insulators 2c includes the plurality of portions P which are separated from each other.

FIG. 4 illustrates positions of the plurality of memory holes MH by broken lines. FIG. 4 further illustrates, by broken lines, the positions of the plurality of cavities C around the memory holes MH. However, in order to avoid difficulty in viewing FIG. 4, FIG. 4 illustrates only several positions of the cavities C by the broken lines. As described above, each of the annular portions of each of the electrode layers 2b is provided in one corresponding cavity C.

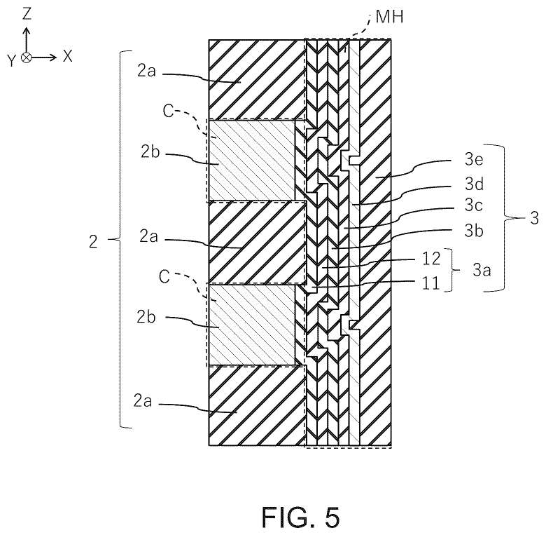

FIG. 5 is a cross-sectional view illustrating the structure of the semiconductor device of the first embodiment. FIG. 5 is the XZ cross section in FIG. 1 while enlarging that.

In FIG. 5, the insulator 11, the insulator 12, the charge storage layer 3b, the tunnel insulator 3c, the channel semiconductor layer 3d, and the core insulator 3e in the columnar portion 3 are in order formed on a right side face of the stacked film 2. In FIG. 5, the side face of the electrode layer 2b is depressed to a left side with respect to the side face of the insulator 2a. As a result, a portion of the columnar portion 3 enters an inside of each of the cavities C.

In the present embodiment, such a depression in the side face of the electrode layer 2b may be produced or may not be produced.

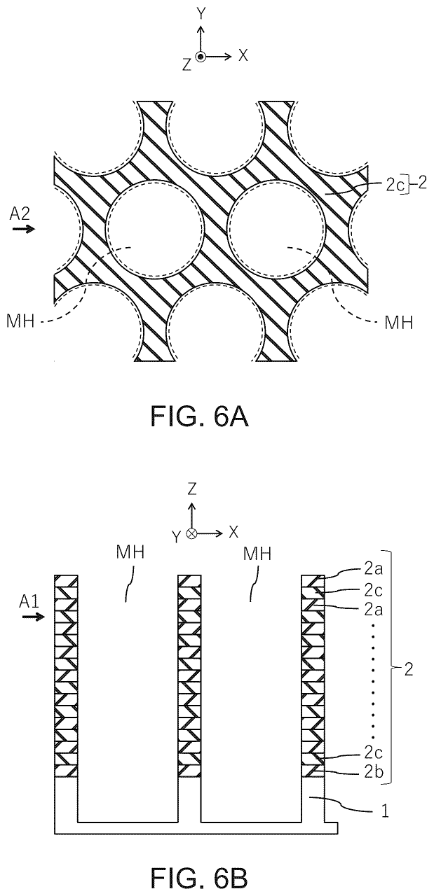

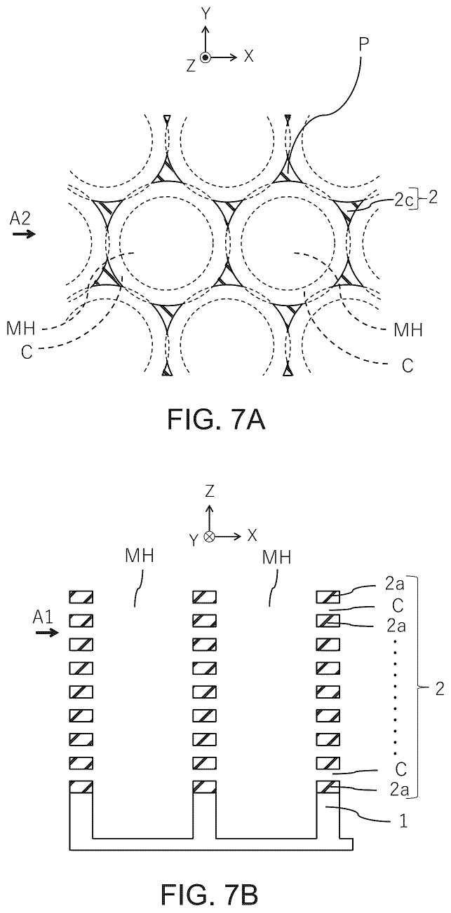

FIGS. 6A to 10B are plan views and cross-sectional views which illustrate a method of manufacturing the semiconductor device of the first embodiment. FIG. 6A is a plan view corresponding to FIG. 2, and FIG. 6B is a cross-sectional view corresponding to FIG. 1. The same applies to FIGS. 7A to 10B.

First, the plurality of insulators 2a and the plurality of insulators 2c are alternately formed on the substrate 1, and the stacked film 2 is thereby formed on the substrate 1 (FIGS. 6A and 6B). As a result, the stacked film 2 is formed to alternately include the plurality of insulators 2a and the plurality of insulators 2c in the Z direction.

Next, by lithography and reactive ion etching (RIE), the plurality of memory holes MH are formed in the stacked film 2 (FIGS. 6A and 6B). Each of the memory holes MH of the present embodiment is formed to pass through the stacked film 2 in the Z direction and reach the substrate 1.

Next, a chemical liquid is supplied into each of the memory holes MH, and the above plurality of insulators 2c are removed from each of the memory holes MH (FIGS. 7A and 7B). As a result, the plurality of cavities C are formed around each of the memory holes MH. Each of the cavities C is formed between the two insulators 2a which are adjacent to each other in the Z direction.

In the present embodiment, the plurality of cavities C in each of the insulators 2c are formed to partially overlap with each other as illustrated in FIG. 7A. As illustrated in FIG. 7A, the plurality of cavities C are formed such that only a portion of the insulator 2c is removed and the plurality of portions P of the insulator 2c remain. In the present embodiment, each of the insulators 2c is removed such that the portions P remain, and it thereby becomes possible to inhibit the stacked film 2 from collapsing after removal of each of the insulators 2c.

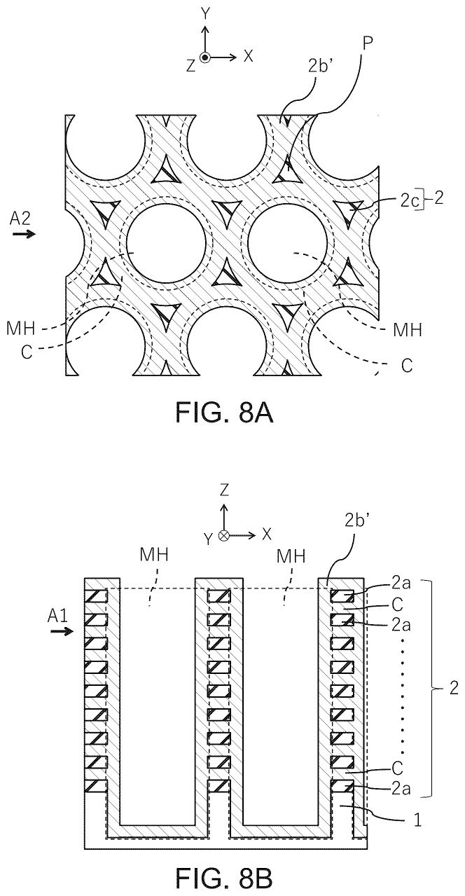

Next, a conductive layer 2b′ is formed on a whole surface of the substrate 1 (FIGS. 8A and 8B). As a result, the conductive layer 2b′ is formed in each of the cavities C and on a side face and a bottom face of each of the memory holes MH and an upper face of the stacked film 2. In FIG. 8B, the conductive layer 2b′ is formed from the plurality of memory holes MH to the inside of each of the cavities C. The conductive layer 2b′ is a Mo layer, for example. The conductive layer 2b′ is formed as a material of the plurality of electrode layers 2b illustrated in FIG. 1.

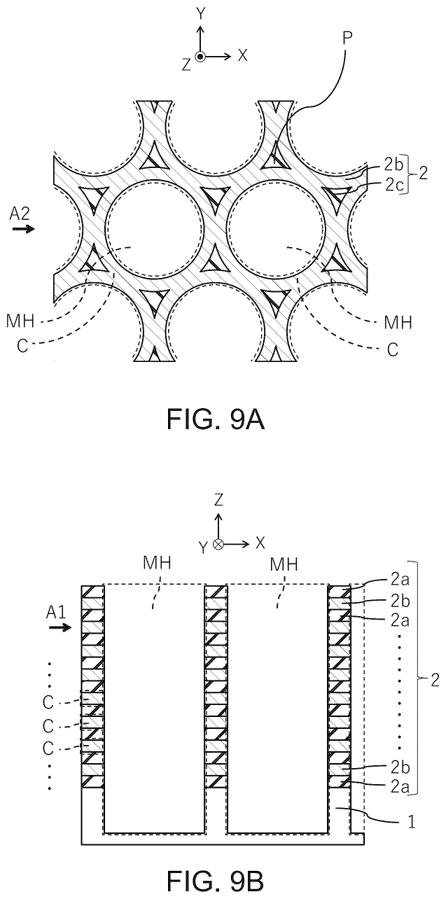

Next, the extra conductive layer 2b′ is removed by etching such that the conductive layer 2b′ remains in each of the cavities C (FIGS. 9A and 9B). As a result, the stacked film 2 which alternately includes the plurality of insulators 2a and the plurality of electrode layers 2b in the Z direction is formed on the substrate 1. In this case, the above-described depression illustrated in FIG. 5 may be produced.

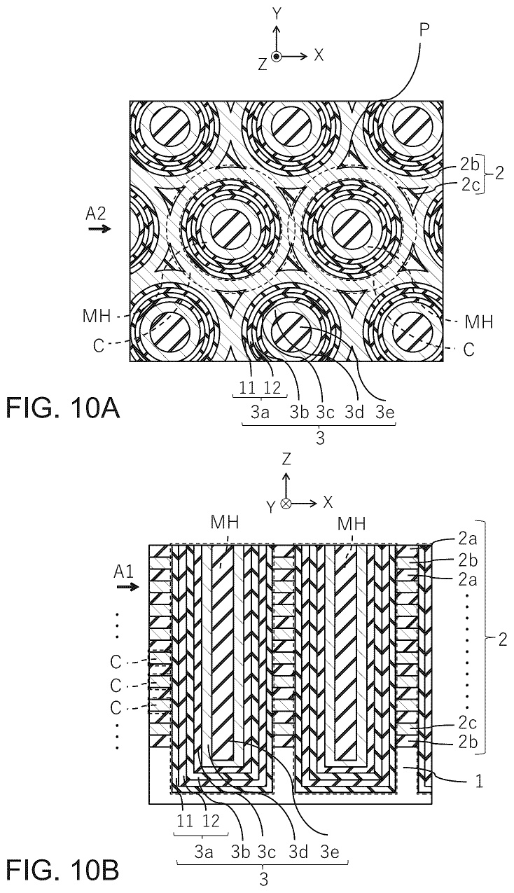

Next, the insulator 11, the insulator 12, the charge storage layer 3b, the tunnel insulator 3c, the channel semiconductor layer 3d, and the core insulator 3e are in order formed on the whole surface of the substrate 1 (FIGS. 10A and 10B). As a result, the columnar portion 3 is formed in each of the memory holes MH.

Next, the extra insulator 11, insulator 12, charge storage layer 3b, tunnel insulator 3c, channel semiconductor layer 3d, and core insulator 3e are removed such that the columnar portion 3 remains in each of the memory holes MH (FIGS. 10A and 10B). In such a manner, the semiconductor device illustrated in FIGS. 1 and 2 is manufactured.

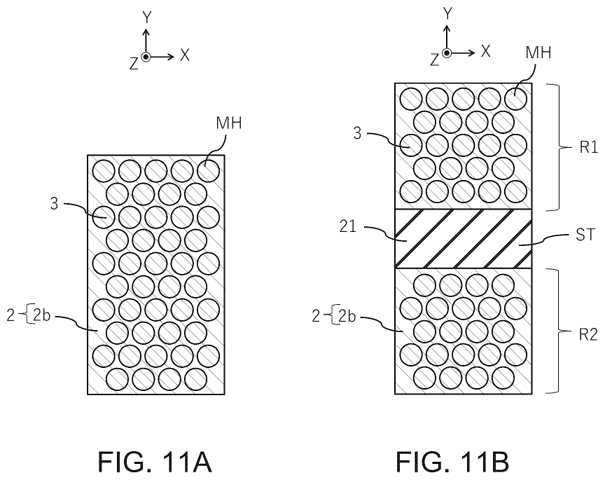

FIGS. 11A and 11B are plan views which illustrate the structure of the semiconductor device of the first embodiment and a structure of a semiconductor device of a comparative example of the first embodiment. FIGS. 11A and 11B are the plan views which correspond to FIG. 2.

As illustrated in FIG. 11B, the semiconductor device of the comparative example includes regions R1 and R2 which are adjacent to each other in the Y direction. Each of the regions R1 and R2 includes the plurality of columnar portions 3. The semiconductor device of the comparative example further includes a slit ST provided between the regions R1 and R2. The slit ST passes through the stacked film 2 in the Z direction and extends in the Z direction and the X direction. The semiconductor device of the comparative example further includes an insulator 21 which is formed in the slit ST. The insulator 21 is a SiO₂ film, for example.

In the comparative example, a replacement step in which the plurality of insulators 2c are replaced by the plurality of electrode layers 2b is performed by using the slit ST. Specifically, the plurality of insulators 2c are removed through the slit ST, a plurality of cavities are thereby formed, and the plurality of electrode layers 2b are formed in the plurality of cavities through the slit ST.

In this case, facts that the slit ST has to be formed for the replacement step, that processing difficulty of the replacement step is high, and that the replacement step takes a long time, and so forth become problems. For example, when the slit ST is formed, a fact that an area of the semiconductor device in the planar view becomes large becomes a problem. As for the processing difficulty, facts that it is difficult to remove the insulator 2c at a position away from the slit ST, that silica is deposited by making high etching selectivity between a SiO₂ film and a SiN film, and so forth become problems.

On the other hand, as illustrated in FIG. 11A, the semiconductor device of the present embodiment includes no slit ST. In the present embodiment, the replacement step in which the plurality of insulators 2c are replaced by the plurality of electrode layers 2b is performed by using the memory holes MH. Specifically, the plurality of insulators 2c are removed through the memory holes MH, the plurality of cavities C are thereby formed, and the plurality of electrode layers 2b are formed in the plurality of cavities C through the memory holes MH.

In the present embodiment, the replacement step is performed without forming the slit ST, and it thereby becomes possible to make small the area of the semiconductor device in the planar view. In the present embodiment, because the insulators 11 and 12 of the block insulator 3a are not yet formed when the insulators 2c are removed, it becomes possible to make low the etching selectivity in removal of the insulators 2c. This makes it possible to inhibit deposition of silica. In the present embodiment, the replacement step is performed by using many small-sized memory holes MH instead of the large-sized slit ST, and it thereby becomes possible to perform the replacement step in a short time and to easily remove the insulators 2c. In the present embodiment, the memory holes MH are used instead of the slit ST, and it thereby becomes possible to easily form the electrode layers 2b.

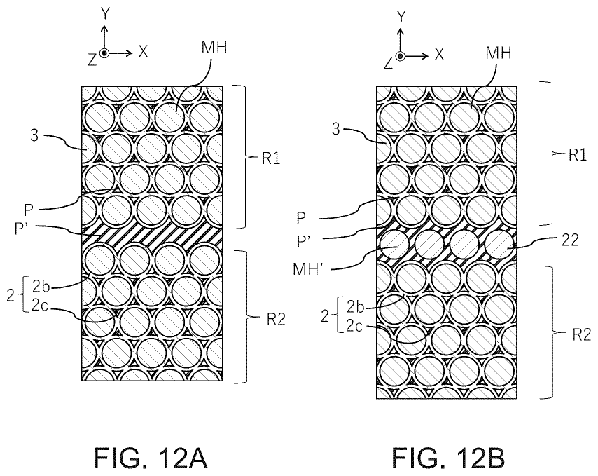

FIGS. 12A and 12B are plan views which illustrate structures of semiconductor devices of first and second modifications of the first embodiment. FIGS. 12A and 12B are the plan views which correspond to FIG. 2.

Similarly to the semiconductor device of the comparative example, the semiconductor device of the first modification includes the regions R1 and R2 which are adjacent to each other in the Y direction (FIG. 12A). FIG. 12A illustrates one insulator 2c in the stacked film 2. The insulator 2c of the present modification includes the plurality of portions P and a portion P′. The portion P′ extends between the plurality of columnar portions 3 in the region R1 and the plurality of columnar portions 3 in the region R2 and extends in the X direction. The portions P′ is an example of a second portion. The regions R1 and R2 are examples of first and second regions.

The present modification makes it possible to divide one electrode layer 2b illustrated in FIG. 12A into a portion in the region R1 and a portion in the region R2. In the present modification, the portion P′ is made small, and it thereby becomes possible to divide the electrode layer 2b while making small the area of the semiconductor device in the planar view. Because a region of the portion P′ is not used for the replacement step as the slit ST, it is possible to make the region of the portion P′ small compared to the slit ST. It is possible to form the portions P and P′ of the present modification by removing the insulator 2c such that the portions P and P′ remain.

The semiconductor device of the second modification has a similar structure to that of the semiconductor device of the first modification (FIG. 12B). The semiconductor device of the present modification further includes a plurality of dummy memory holes MH′ which are formed in the portion P′. Each of the dummy memory holes MH′ has a similar shape to the memory hole MH and extends in the portion P′ in the Z direction. The semiconductor device of the present modification further includes an interconnect layer 22 which is formed in each of the of dummy memory holes MH′. The interconnect layer 22 is a metal layer or a semiconductor layer, for example. The interconnect layer 22 in each of the dummy memory holes MH′ is used as an interconnect which electrically connects configuration elements of the stacked film 2 on the upper side to configuration elements of the stacked film 2 on the lower side, for example. The interconnect layer 22 in each of the dummy memory holes MH′ is electrically connected to the substrate 1, for example. The interconnect layer 22 is an example of a third conductive layer.

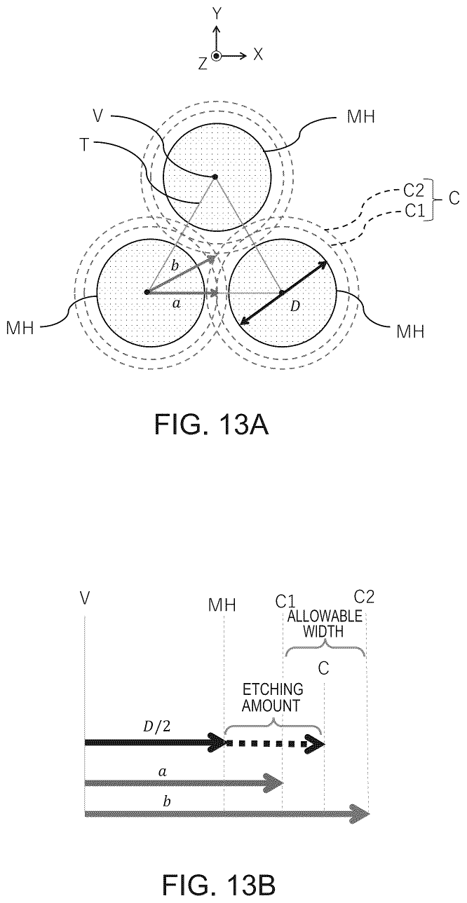

FIGS. 13A and 13B are a plan view and a graph for explaining dimensions of the semiconductor device of the first embodiment.

FIG. 13A illustrates three memory holes MH which are adjacent to each other and three cavities C which surround the memory holes MH. FIG. 13A further illustrates a diameter D of each of the memory holes MH, centers V of the three memory holes MH, and a triangle T which is formed with the centers V. The triangle T illustrated in FIG. 13A is an equilateral triangle.

FIG. 13A illustrates, as examples of the cavity C, an allowable minimum cavity C1 and an allowable maximum cavity C2. FIG. 13A further illustrates a radius “a” of the cavity C1 and a radius “b” of the cavity C2. The radius “a” is a minimum value of the radius of the cavity C, and the radius “b” is a maximum value of the radius of the cavity C.

The radius “a” is a lower limit value at which the three cavities C illustrated in FIG. 13A contact with each other. When the radius of each of the cavities C is set smaller than the radius “a”, the cavities C do not contact with each other, and each of the electrode layers 2b (FIGS. 1 and 2) is separated for each of the cavities C.

The radius “b” is a lower limit value at which the three cavities C illustrated in FIG. 13A contact with each other such that no gap remains among the cavities C. When the radius of each of the cavities C is set larger than the radius “b”, the portions P of each of the insulators 2c (FIGS. 2 and 4) do not remain.

While setting the same center V as a starting point, FIG. 13B illustrates a radius “D/2” of the memory hole MH, the radius “a” of the cavity C1, and the radius “b” of the cavity C2. Among the radii “D/2”, “a”, and “b”, a relationship of D/2<a<b holds.

An “etching amount” indicated in FIG. 13B represents an amount of etching for forming the cavity C from the memory hole MH. The etching amount of the present embodiment has to be set such that the radius of the cavity C falls in a range from “a” to “b”. An “allowable width” indicated in FIG. 13B represents a width of the range.

In the present embodiment, an etching margin in forming the cavity C from the memory MH is expressed by the following expression (1).

Etching margin=allowable width÷etching amount (1)

The etching amount in the expression (1) represents the amount of etching in a case where the radius of the cavity C becomes “(a+b)/2”. Here, “(a+b)/2” represents an average value of the radius “a” and the radius “b”. The etching amount in the expression (1) is expressed by the following expression (2).

Etching amount=(a+b)/2−D/2 (2)

Meanwhile, the allowable width in the expression (1) is expressed by the following expression (3).

Allowable width=b−a (3)

When the radii “D/2”, “a”, and “b” of the present embodiment are set, it is desirable that the radii “D/2”, “a”, and “b” be set such that the etching margin in the expression (1) becomes large.

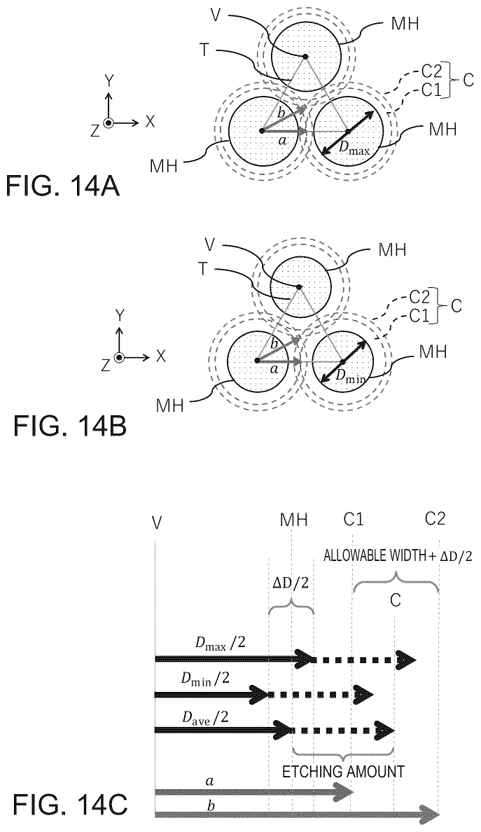

FIGS. 14A to 14C are plan views and a graph for explaining dimensions of a semiconductor device of a third modification of the first embodiment.

The semiconductor device of the present modification has a similar structure to that of the semiconductor device of the first embodiment, which is illustrated in FIGS. 1, 2, and so forth. However, each of the memory holes MH of the present modification has a different diameter “D” in accordance with a height.

FIGS. 14A and 14B are the plan views which correspond to FIG. 13A. However, FIG. 14A illustrates an XY cross section for a height with which the diameter “D” of each of the memory holes MH becomes a maximum value “Dₘₐₓ”, and FIG. 14B illustrates an XY cross section for a height with which the diameter “D” of each of the memory holes MH becomes a minimum value “Dₘᵢₙ”.

FIG. 14C is the graph which corresponds to FIG. 13B. While setting the same center V as a start point, FIG. 14C illustrates a maximum radius “Dₘₐₓ/2” of the memory hole MH, a minimum radius “Dₘᵢₙ/2” of the memory hole MH, an average radius “Dₐᵥₑ/2” of the memory hole MH, the radius “a” of the cavity C1, and the radius “b” of the cavity C2. Among the radii “Dₘₐₓ/2”, “Dₘᵢₙ/2”, “Dₐᵥₑ/2”, “a”, and “b”, a relationship of Dₘᵢₙ/2<Dₐᵥₑ/2<Dₘₐₓ<a<b and a relationship of Dₐᵥₑ=(Dₘₐₓ+Dₘᵢₙ)/2 hold. FIG. 14C further illustrates “ΔD/2” as a difference between the maximum radius Dₘₐₓ/2 and the minimum radius Dₘᵢₙ/2 (ΔD/2=Dₘₐₓ/2−Dₘᵢₙ/2).

Similarly to the etching margin of the first embodiment, the etching margin of the present modification is expressed by the above expression (1). On the other hand, the etching amount of the present modification is expressed by the following expression (4), and the allowable width of the present modification is expressed by the following expression (5).

Etching amount=(a+b)/2−Dₐᵥₑ/2 (4)

Allowable width=b−a−ΔD/2 (5)

The etching amount of the present modification represents an average amount of etching for forming the cavity C from the memory hole MH. Meanwhile, the allowable width of the present modification is a value resulting from subtraction of “ΔD/2”, which is dispersion of the radius “D/2”, from the allowable width “b−a” of the first embodiment.

When the radii “D/2”, “a”, and “b” of the present modification are set, it is desirable that the radii “D/2”, “a”, and “b” be set such that the etching margin in the expression (1) becomes large. However, the expression (1) in the present modification is calculated by using the expression (4) and the expression (5).

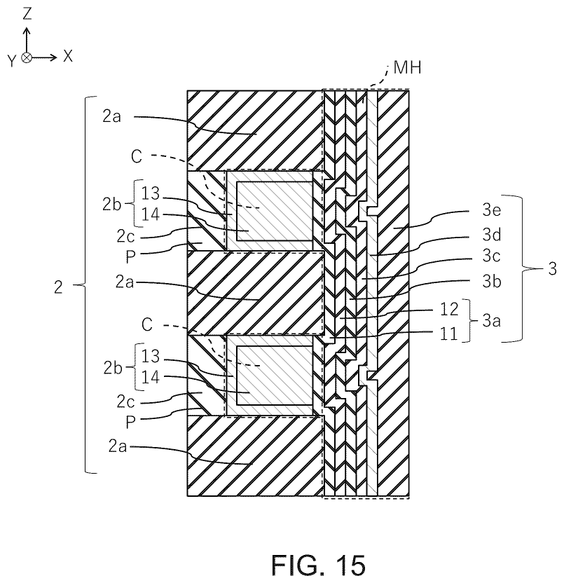

FIG. 15 is a cross-sectional view illustrating a structure of a semiconductor device of a fourth modification of the first embodiment.

The semiconductor device of the present modification has a similar structure to that of the semiconductor device of the first embodiment, which is illustrated in FIG. 5. However, FIG. 15 illustrates three insulators 2a, two electrode layers 2b, and two insulators 2c, which are included in the stacked film 2. FIG. 15 further illustrates two portions P which are included in the two insulators 2c.

In FIG. 15, each of the electrode layers 2b of the present modification contacts with two insulators 2a and one portion P. Here, each of the electrode layers 2b of the present modification includes a barrier metal layer 13, which is formed on an upper face of one insulator 2a, a lower face of the other insulator 2a, and a side face of the portion P, and an electrode material layer 14, which is formed on an upper face, a lower face, and a side face of the barrier metal layer 13. The barrier metal layer 13 is a TiN film (titanium nitride film), for example. The electrode material layer 14 is a W (tungsten) layer, for example. The barrier metal layer 13 is an example of a first conductive layer, and the electrode material layer 14 is an example of a second conductive layer.

It is possible to form each of the electrode layers 2b of the present modification by forming the conductive layer 2b′ which in order includes the barrier metal layer 13 and the electrode material layer 14 in a step illustrated in FIGS. 8A and 8B.

As described above, the replacement step of the present embodiment is performed by using the memory holes MH instead of the slit ST. This makes it possible to form the insulator 11 (block insulator 3a) which has a shape illustrated in FIG. 1 and so forth and the electrode layer 2b and the insulator 2c which have shapes illustrated in FIG. 2 and so forth. In the present embodiment, the replacement step is performed by using the memory holes MH, and it thereby becomes possible to form a suitable electrode layer 2b which can solve various problems in formation of the electrode layer 2b, for example.

### Second Embodiment

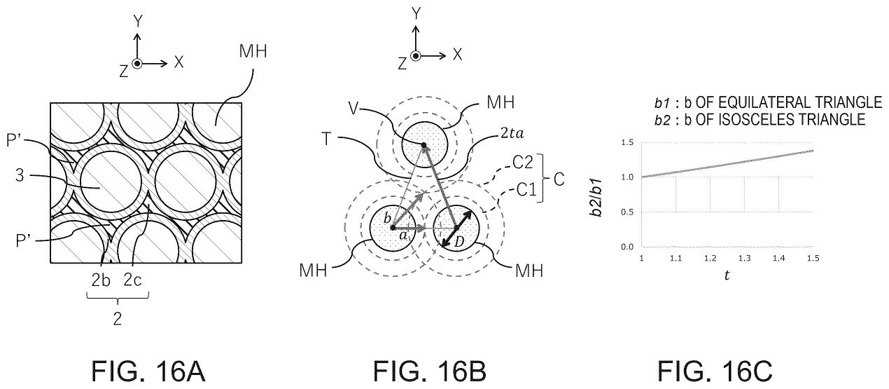

FIGS. 16A to 16C are plan views and a graph for explaining a structure of a semiconductor device of a second embodiment.

FIG. 16A is the plan view which corresponds to FIGS. 2, 11A, and so forth. FIG. 16B is the plan view which corresponds to FIG. 13A and so forth. As illustrated in FIGS. 16A and 16B, the semiconductor device of the present embodiment includes a plurality of columnar portions 3 (memory holes MH) which are arranged in the shape of the triangular lattice in the planar view. In the present embodiment, the triangular lattice is formed with a plurality of isosceles triangles. The triangle T illustrated in FIG. 16B is an isosceles triangle.

One insulator 2c illustrated in FIG. 16A includes a plurality of portions P and a plurality of portions P′. The portions P′ illustrated in FIG. 16A extend in the X direction and divide one electrode layer 2b into a plurality of portions similarly to the portion P′ illustrated in FIG. 12A. Those portions of the electrode layer 2b extend in the X direction. Each of the portions P′ illustrated in FIG. 16A is an example of the second portion.

The triangle T illustrated in FIG. 16B includes one side having a length “2a” and two sides having lengths “2ta”. In the present embodiment, a value of “t” is set sufficiently large, and it thereby becomes possible to form the plurality of portions P′ in the insulator 2c. The present embodiment makes it possible to effectively inhibit collapse of the stacked film 2 by the portions P′.

FIG. 16C is the graph for comparing a case where the triangle T is an equilateral triangle with a case where the triangle T is an isosceles triangle. A value “b1” represents a length of each side of the triangle T in a case where the triangle T is an equilateral triangle. A value “b2” represents a length of equal sides of the triangle T in a case where the triangle T is an isosceles triangle. Here, b1=2a, and b2=2ta. FIG. 16C is the graph in which the horizontal axis represents “t” and the vertical axis represents “b2/b1”.

In the present embodiment, the triangular lattice is formed with the plurality of isosceles triangles, and it thereby becomes possible to form the portions P′ in the insulator 2c. This makes it possible to effectively inhibit collapse of the stacked film 2.

### Third Embodiment

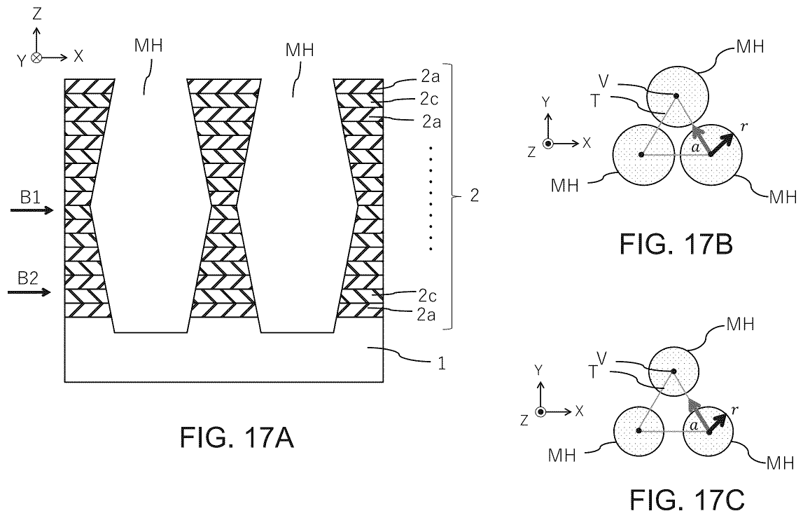

FIGS. 17A to 17C are a cross-sectional view and plan views for explaining a structure of a semiconductor device of a third embodiment.

FIG. 17A is the cross-sectional view which corresponds to FIG. 6B. Each of the memory holes MH of the present embodiment has a different radius in accordance with the height. In FIG. 17A, the radius of the each of the memory holes MH becomes small in the vicinities of an upper end and a lower end of each of the memory holes MH and becomes large between the upper end and the lower end.

FIG. 17B illustrates an XY cross section at a position of an arrow B1 indicated in FIG. 17A, and FIG. 17C illustrates an XY cross section at a position of an arrow B2 indicated in FIG. 17A. FIGS. 17B and 17C illustrate a radius “r” of each of the memory holes MH. Each of the memory holes MH of the present embodiment has the different radius “r” in accordance with the height.

In FIG. 17A, the insulator 2c at the position of the arrow B1 has a portion which is interposed between the left-side memory hole MH and the right-side memory hole MH. In the following, this portion will be referred to as an “intermediate portion”. At the position of the arrow B1, when the radius “r” (FIG. 17B) of each of the memory holes MH becomes larger, a width of the intermediate portion becomes shorter, and the portions P of the insulator 2c might not remain after wet etching illustrated in FIGS. 7A and 7B. Note that the portions P are the intermediate portions which remain after the wet etching. However, the portions P do not remain in the cross section illustrated in FIG. 17A but may remain in a cross section different from the cross section illustrated in FIG. 17A (for example, the portions P do not remain in the cross section illustrated in FIG. 7B).

In addition, in FIG. 17A, the insulator 2c at the position of the arrow B2 has the intermediate portion which is interposed between the left-side memory hole MH and the right-side memory hole MH. At the position of the arrow B2, when the radius “r” (FIG. 17C) of each of the memory holes MH becomes smaller, the width of the intermediate portion becomes longer, and the cavities C might not contact with each other after the wet etching illustrated in FIGS. 7A and 7B.

FIG. 17A illustrates a plurality of insulators 2c in the stacked film 2, and in addition, a plurality of intermediate portions are provided which are interposed between the left-side memory hole MH and the right-side memory hole MH. In the present embodiment, it is desirable that the widths of the intermediate portions resulting from the above wet etching be inhibited from changing in accordance with the height. That is, it is desirable that widths of a plurality of portions P formed with the intermediate portions be inhibited from changing in accordance with the height.

Accordingly, before the stacked film 2 of the present embodiment is formed, the shape of each of the memory holes MH is predicted by simulation. In a case where the radius “r” in a certain insulator 2c becomes large in the simulation, when the insulator 2c is formed, a film quality of the insulator 2c is set such that an etching rate of the insulator 2c becomes low. On the other hand, in a case where the radius “r” in a certain insulator 2c becomes small in the simulation, when the insulator 2c is formed, the film quality of the insulator 2c is set such that the etching rate of the insulator 2c becomes high. This makes it possible to inhibit the widths of the above plurality of portions P from changing in accordance with the height. The film qualities are examples of first and second film qualities. Kinds of the film qualities of the plurality of insulators 2c in the stacked film 2 may be three or more kinds.

Each of the insulators 2c of the present embodiment is a SiN film, for example. The film quality of each of the insulators 2c is adjustable based on a density of each of the insulators 2c or a concentration of impurity oxygen atoms in each of the insulators 2c.

In the present embodiment, the film qualities of the plurality of insulators 2c in the stacked film 2 are changed for each of the insulators 2c, and it thereby becomes possible to inhibit the widths of the above plurality of portions P from changing in accordance with the height.

### Fourth Embodiment

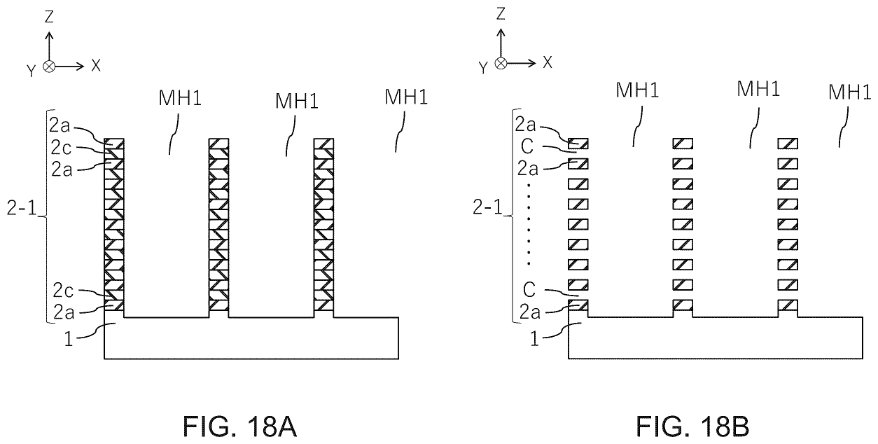

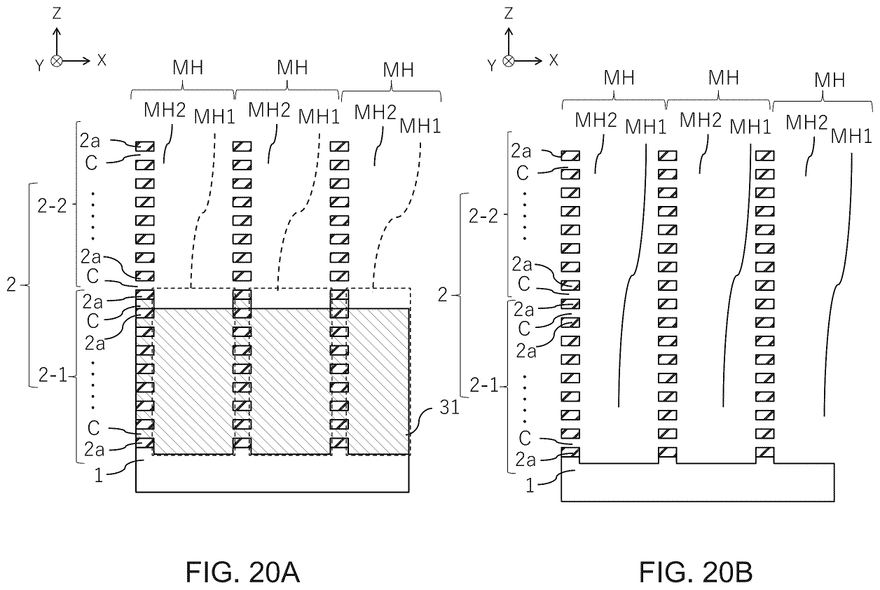

FIGS. 18A to 20B are cross-sectional views illustrating a method of manufacturing a semiconductor device of a fourth embodiment. FIGS. 18A and 20B are the cross-sectional views which correspond to FIG. 1. The method of manufacturing the semiconductor device of the present embodiment, which is illustrated in FIGS. 18A to 20B, corresponds to a modification of the method of manufacturing the semiconductor device of the first embodiment, which is illustrated in FIGS. 6A to 10B.

First, a plurality of insulators 2a and a plurality of insulators 2c are alternately formed on the substrate 1, and a lower stacked film 2-1 is thereby formed on the substrate 1 (FIG. 18A). As a result, the lower stacked film 2-1 is formed to alternately include the plurality of insulators 2a and the plurality of insulators 2c in the Z direction. The lower stacked film 2-1 corresponds to a portion of the stacked film 2.

Next, by the lithography and the RIE, a plurality of lower memory holes MH1 are formed in the lower stacked film 2-1 (FIG. 18A). Each of the lower memory holes MH1 of the present embodiment is formed to pass through the lower stacked film 2-1 in the Z direction and reach the substrate 1. Each of the lower memory holes MH1 corresponds to a portion of one memory hole MH. Each of the lower memory holes MH1 is an example of a lower portion of the first concave portion. A step illustrated in FIG. 18A is performed as in the step illustrated in FIGS. 6A and 6B.

Next, a chemical liquid is supplied into each of the lower memory holes MH1, and the above plurality of insulators 2c are removed from each of the lower memory holes MH1 (FIG. 18B). As a result, a plurality of cavities C are formed around each of the lower memory holes MH1. Each of the cavities C is formed between the two insulators 2a which are adjacent to each other in the Z direction. The cavities C are examples of the second concave portion and a third concave portion. A step illustrated in FIG. 18B is performed as in the step illustrated in FIGS. 7A and 7B.

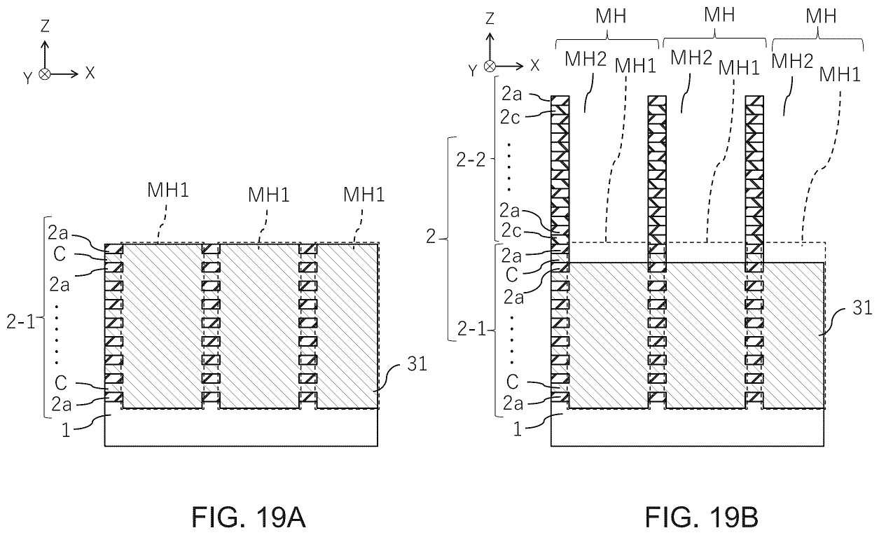

Next, a sacrificial layer 31 is formed in the plurality of lower memory holes MH1 and the plurality of cavities C which are provided in the lower stacked film 2-1 (FIG. 19A). The sacrificial layer 31 is an amorphous Si layer or an amorphous C (carbon) layer, for example. The sacrificial layer is an example of a first film.

Next, a plurality of insulators 2a and a plurality of insulators 2c are alternately formed on the lower stacked film 2-1 and the sacrificial layer 31, and an upper stacked film 2-2 is thereby formed on the lower stacked film 2-1 and the sacrificial layer 31 (FIG. 19B). As a result, the upper stacked film 2-2 is formed to alternately include the plurality of insulators 2a and the plurality of insulators 2c in the Z direction. The upper stacked film 2-2 corresponds to a portion of the stacked film 2.

Next, by the lithography and the RIE, a plurality of upper memory holes MH2 are formed in the upper stacked film 2-2 (FIG. 19B). Each of the upper memory holes MH2 of the present embodiment is formed to pass through the upper stacked film 2-2 in the Z direction and reach the sacrificial layer 31 in the corresponding lower memory hole MH1. Each of the upper memory holes MH2 corresponds to a portion of one memory hole MH. Each of the upper memory holes MH2 is an example of an upper portion of the first concave portion. A step illustrated in FIG. 19B is performed as in the step illustrated in FIGS. 6A and 6B.

Next, a chemical liquid is supplied into each of the upper memory holes MH2, and the above plurality of insulators 2c are removed from each of the upper memory holes MH2 (FIG. 20A). As a result, the plurality of cavities C are formed around each of the upper memory holes MH2. Each of the cavities C is formed between the two insulators 2a which are adjacent to each other in the Z direction. The cavities C are examples of the second concave portion and a fourth concave portion. A step illustrated in FIG. 20A is performed as in the step illustrated in FIGS. 7A and 7B.

Next, the sacrificial layer 31 is removed from the plurality of lower memory holes MH1 and the plurality of cavities C which are provided in the lower stacked film 2-1 (FIG. 20B). In such a manner, the stacked film 2 is formed to include the lower stacked film 2-1 and the upper stacked film 2-2, and each of the memory holes MH is formed to include one lower memory hole MH1 and one upper memory hole MH2.

Subsequently, steps illustrated in FIGS. 8A to 10B are performed. In such a manner, the semiconductor device, which has a similar structure to that of the semiconductor device illustrated in FIG. 1, is manufactured.

In the present embodiment, the stacked film 2 is formed by separately forming the lower stacked film 2-1 and the upper stacked film 2-2, and it thereby becomes possible to easily form the stacked film 2 including a large number of insulators 2a and 2c and the memory hole MH with a large aspect ratio, for example.

Note that the stacked film 2 of the present embodiment includes two partial stacked films (the lower stacked film 2-1 and the upper stacked film 2-2) but may instead include three or more partial stacked films. Each of the memory holes MH of the present embodiment may be formed to include a joint portion in the vicinity of a boundary portion between the lower memory hole MH1 and the upper memory hole MH2.

### Fifth Embodiment

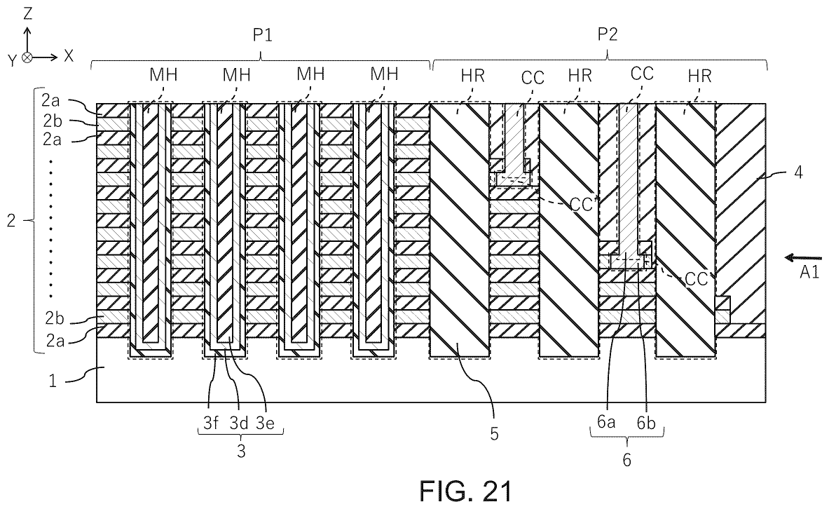

FIG. 21 is a cross-sectional view illustrating a structure of a semiconductor device of a fifth embodiment. FIG. 21 is the cross-sectional view which corresponds to FIG. 1.

The semiconductor device of the present embodiment has a similar structure to that of the semiconductor device of the first embodiment, which is illustrated in FIGS. 1, 2, and so forth. However, the stacked film 2 of the present embodiment includes a flat portion P1 and a stair structure portion P2. The flat portion P1 has an upper face having a flat shape. The stair structure portion P2 has upper faces and side faces which have a stair-like shape.

The flat portion P1 has a structure similar to that of the stacked film 2 illustrated in FIG. 1. FIG. 21 illustrates a plurality of columnar portions 3 (memory holes MH) which are formed in the stacked film 2. A memory insulator 3f in each of the columnar portions 3 in order includes the insulator 11, the insulator 12, the charge storage layer 3b, and the tunnel insulator 3c.

Each stage of the stair structure portion P2 is formed with one insulator 2a, one electrode layer 2b, and one insulator 2c (not illustrated). However, a lowest stage of the stair structure portion P2 is formed only with one insulator 2a.

The semiconductor device of the present embodiment further includes an inter layer dielectric 4, a plurality of beam portions 5, and a plurality of contact plugs 6. Each of the contact plugs 6 includes a plug body 6a and a plug base 6b. Each of the beam portions 5 is an example of a sixth insulator, and each of the contact plugs 6 is an example of a plug. The plug body 6a is an example of an upper portion of the plug, and the plug base 6b is an example of a lower portion of the plug.

The inter layer dielectric 4 is formed on the stair structure portion P2 to eliminate a level difference between an upper face of the flat portion P1 and an upper face of the stair structure portion P2. The inter layer dielectric 4 is a SiO₂ film, for example.

FIG. 21 further illustrates a plurality of holes HR which are formed in the stair structure portion P2 and the inter layer dielectric 4. Each of the holes HR extends in the Z direction and has a circular shape in the planar view. Each of the holes HR of the present embodiment passes through the inter layer dielectric 4 and the stair structure portion P2 in the Z direction and reaches the substrate 1.

Each of the beam portions 5 is formed in one corresponding hole HR. Thus, each of the beam portions 5 extends in the Z direction and has a circular shape in the planar view. Each of the beam portions 5 of the present embodiment passes through the inter layer dielectric 4 and the stair structure portion P2 in the Z direction and reaches the substrate 1. Each of the beam portions 5 is formed with an insulator such as a SiO₂ film, for example. Each of the beam portions 5 of the present embodiment functions as a beam for inhibiting collapse of the stacked film 2.

FIG. 21 further illustrates a plurality of contact holes CC and a plurality of expanded contact holes CC′ which are formed in the stair structure portion P2 and the inter layer dielectric 4. Each of the contact holes CC extends in the Z direction and has a circular shape in the planar view. As illustrated in FIG. 21, each of the contact holes CC of the present embodiment passes through the inter layer dielectric 4 and one insulator 2a in the Z direction. Meanwhile, each of the expanded contact holes CC′ is provided below one corresponding contact hole CC. As illustrated in FIG. 21, each of the expanded contact holes CC′ of the present embodiment is provided in one electrode layer 2b.

Each of the contact plugs 6 includes the plug body 6a which is formed in one corresponding contact hole CC and the plug base 6b which is formed in one corresponding expanded contact hole CC′. Thus, the plug body 6a of each of the contact plugs 6 extends in the Z direction and has a circular shape in the planar view. The plug base 6b of each of the contact plugs 6 is provided in one electrode layer 2b below the plug body 6a and is formed on the side face of the electrode layer 2b. As a result, each of the contact plugs 6 is electrically connected to one corresponding electrode layer 2b. Each of the contact plugs 6 is a metal plug including a Mo layer or a W layer, for example.

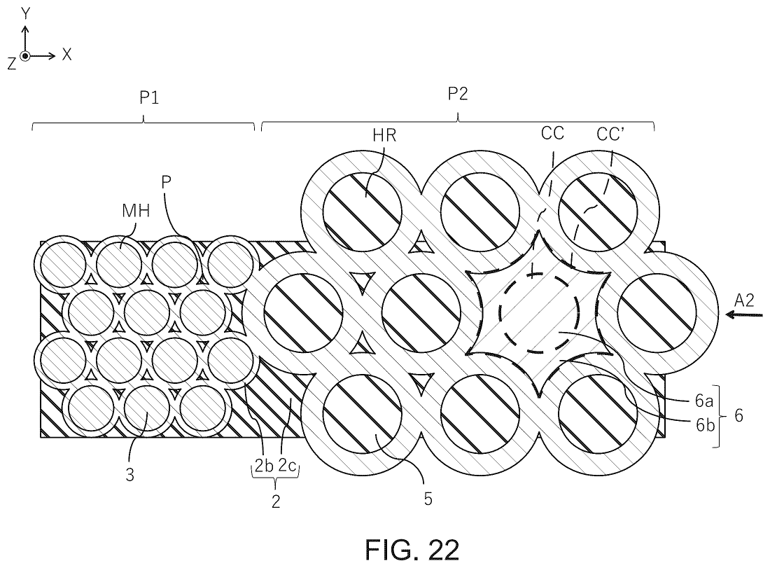

FIG. 22 is a plan view illustrating the structure of the semiconductor device of the fifth embodiment. FIG. 22 illustrates an XY cross section at a position of an arrow A1 indicated in FIG. 21. Meanwhile, FIG. 21 illustrates an XZ cross section at a position of an arrow A2 indicated in FIG. 22.

The flat portion P1 illustrated in FIG. 22 has a structure similar to that of the stacked film 2 illustrated in FIG. 2. For example, the plurality of columnar portions 3 illustrated in FIG. 22 are arranged in the shape of the triangular lattice. The triangular lattice is formed with a plurality of equilateral triangles. One insulator 2c illustrated in FIG. 22 includes a plurality of portions P which are formed in one electrode layer 2b. The electrode layer 2b has a shape including a plurality of annular portions which partially overlap with each other, and each of the columnar portions 3 is annularly surrounded by one annular portion.

Meanwhile, in the stair structure portion P2 illustrated in FIG. 22, the plurality of beam portions 5 are arranged similarly to the above plurality of columnar portions 3. For example, the beam portions 5 are arranged in the shape of the triangular lattice. The triangular lattice is formed with a plurality of equilateral triangles. The above-described electrode layer 2b includes the plurality of annular portions not only in the flat portion P1 but also in the stair structure portion P2, and each of the beam portions 5 is annularly surrounded by one annular portion. The plurality of annular portions in the flat portion P1 and the stair structure portion P2 are arranged to partially overlap with each other. Each of the annular portions in the flat portion P1 is an example of the surrounding portion which surrounds the columnar portion, and each of the annular portions in the stair structure portion P2 is an example of the surrounding portion which surrounds the beam portion (sixth insulator). In the planar view, a diameter of each of the beam portions 5 is set larger than a diameter of each of the columnar portions 3 in the present embodiment but may instead be set equal to or smaller than the diameter of each of the columnar portions 3.

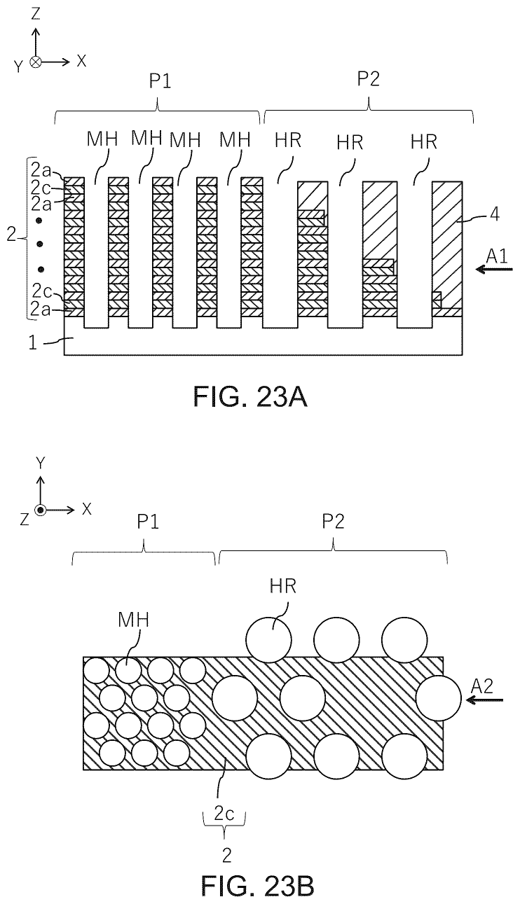

In addition, in the stair structure portion P2 illustrated in FIG. 22, at one lattice point of the triangular lattice, one contact plug 6 is arranged instead of one beam portion 5. In FIG. 23, the plug body 6a (contact hole CC) has the circular shape in the planar view, and the plug base 6b (expanded contact hole CC′) has a shape close to a hexagon in the planar view. In FIG. 23, the plug base 6b contacts with six annular portions in the electrode layer 2b, and as a result, the contact plug 6 is electrically connected to the electrode layer 2b. In the planar view, a diameter of each of the contact plugs 6 is set larger than the diameter of each of the columnar portions 3 in the present embodiment but may instead be set equal to or smaller than the diameter of each of the columnar portions 3. In the planar view, the diameter of each of the contact plugs 6 is set to the same value as the diameter of each of the beam portions 5 in the present embodiment but may instead be set to a different value from the diameter of each of the beam portions 5.

Note that as for the insulator 2c illustrated in FIG. 22, for visibility of the insulator 2c, only a portion of the insulator 2c is illustrated in FIG. 22.

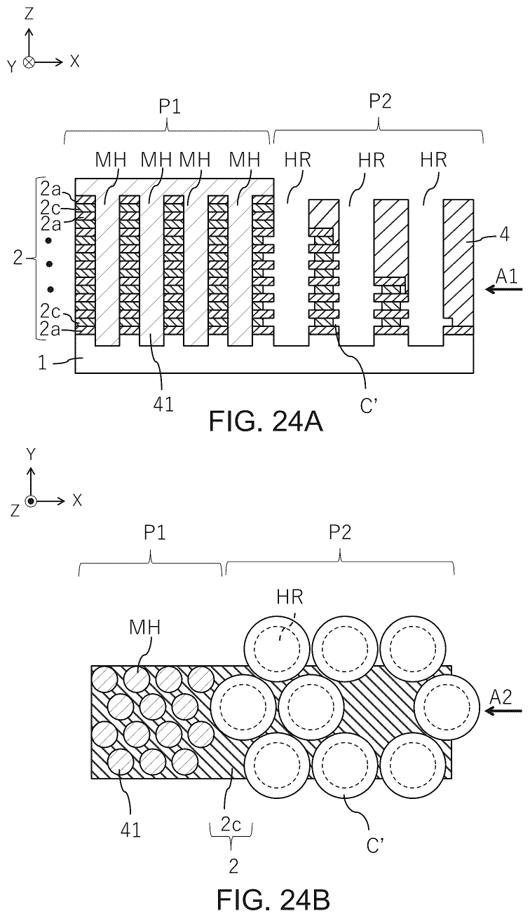

FIGS. 23A to 29B are cross-sectional views and plan views which illustrate a method of manufacturing the semiconductor device of the fifth embodiment. FIG. 23A is the cross-sectional view corresponding to FIG. 21, and FIG. 23B is the plan view corresponding to FIG. 22. The same applies to FIGS. 24A to 29B.

First, a plurality of insulators 2a and a plurality of insulators 2c are alternately formed on the substrate 1, and the stacked film 2 is thereby formed on the substrate 1 (FIGS. 23A and 23B). As a result, the stacked film 2 is formed to alternately include the plurality of insulators 2a and the plurality of insulators 2c in the Z direction. By the lithography and the RIE, the stacked film 2 of the present embodiment is formed to include the flat portion P1 and the stair structure portion P2.

Next, the inter layer dielectric 4 is formed on the stair structure portion P2 (FIGS. 23A and 23B). Next, by the lithography and the RIE, a plurality of memory holes MH and the plurality of holes HR are formed in the stacked film 2 (FIGS. 23A and 23B). Each of the memory holes MH of the present embodiment is formed to pass through the flat portion P1 in the Z direction and reach the substrate 1. Meanwhile, each of the holes HR of the present embodiment is formed to pass through the inter layer dielectric 4 and the stair structure portion P2 in the Z direction and reach the substrate 1.

Next, a mask layer 41 is formed on the stacked film 2 (FIGS. 24A and 24B). The mask layer 41 of the present embodiment is formed such that the flat portion P1 is covered by the mask layer 41 and the stair structure portion P2 is exposed from the mask layer 41. The mask layer 41 is also formed in each of the memory holes MH. The mask layer 41 is a C (carbon) layer, for example.

Next, a chemical liquid is supplied into each of the holes HR, and the above plurality of insulators 2c in the stair structure portion P2 are removed from each of the holes HR (FIGS. 24A and 24B). As a result, a plurality of cavities C′ are formed around each of the holes HR. Each of the cavities C′ is formed between two insulators 2a which are adjacent to each other in the Z direction. Subsequently, the mask layer 41 is removed.

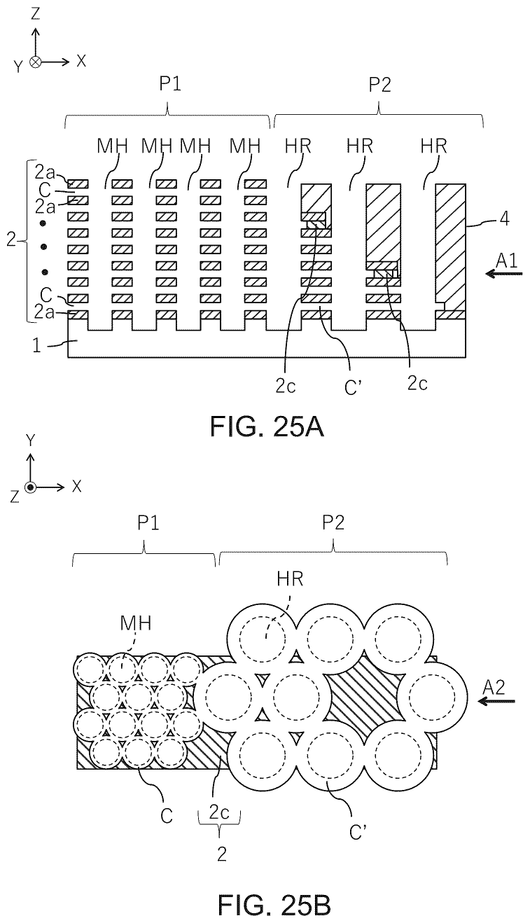

Next, a chemical liquid is supplied into each of the memory holes MH and each of the holes HR, and the above plurality of insulators 2c are removed from each of the memory holes MH and each of the holes HR (FIGS. 25A and 25B). As a result, the plurality of cavities C are formed around each of the memory holes MH, and a radius of each of the cavities C′ becomes large. Each of the cavities C is formed between the two insulators 2a which are adjacent to each other in the Z direction.

In the present embodiment, the plurality of cavities C and C′ in each of the insulators 2c are formed to partially overlap with each other as illustrated in FIG. 25B. As illustrated in FIG. 25B, the plurality of cavities C and C′ are formed such that only a portion of the insulator 2c is removed and the insulator 2c partially remains. In the present embodiment, each of the insulators 2c is removed such that each of the insulators 2c partially remains, and it thereby becomes possible to inhibit the stacked film 2 from collapsing after removal of each of the insulators 2c.

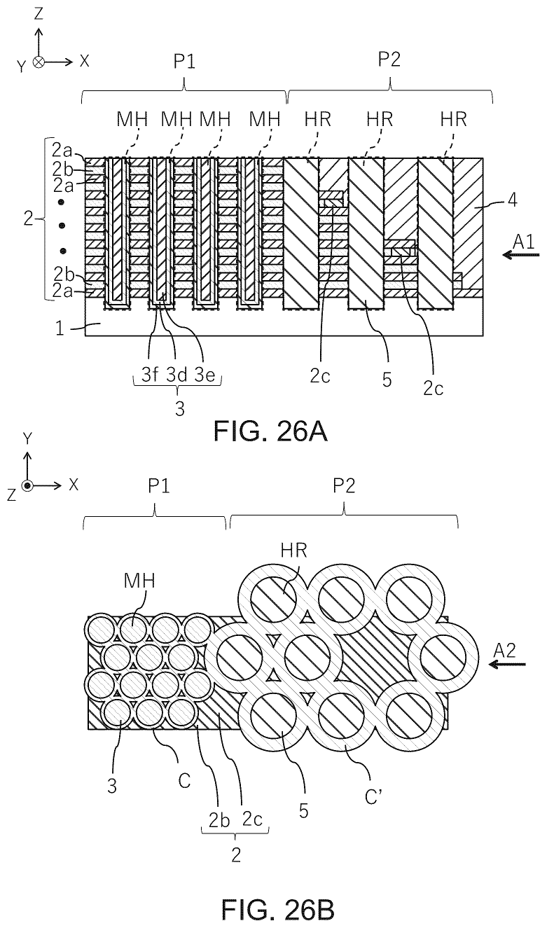

Next, the columnar portion 3 is formed in each of the memory holes MH, and the beam portion 5 is formed in each of the holes HR (FIGS. 26A and 26B).

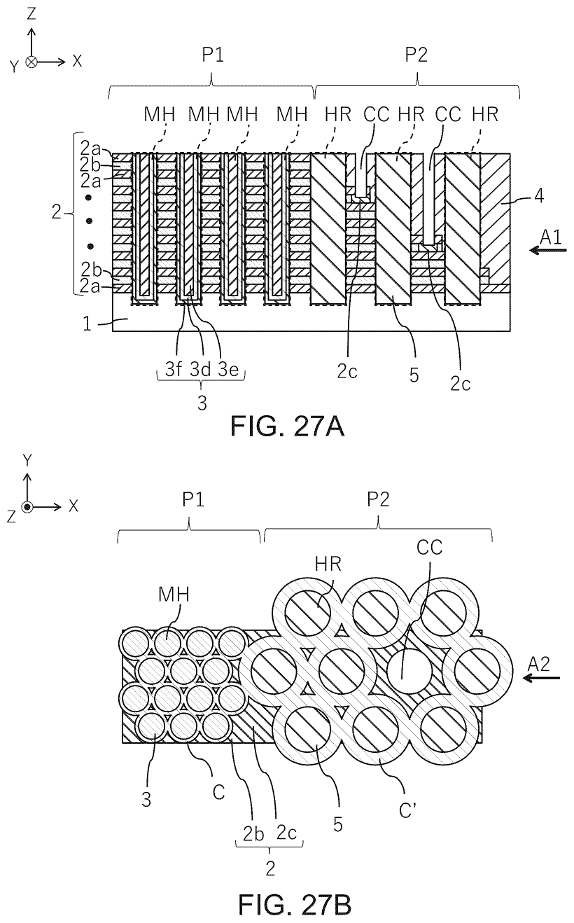

Next, by the lithography and the RIE, the plurality of contact holes CC are formed in the stacked film 2 (FIGS. 27A and 27B). Each of the contact holes CC of the present embodiment is formed to pass through the inter layer dielectric 4 and one insulator 2a in the Z direction and reach one insulator 2c.

In FIG. 27A, each of the contact holes CC is formed in a portion above the insulator 2c. As illustrated in FIG. 27B, the portion of the insulator 2c is surrounded by six cavities C′. In the electrode layer 2b illustrated in FIG. 27A, a portion in each of the cavities C′ in the electrode layer 2b corresponds to one annular portion of the electrode layer 2b.

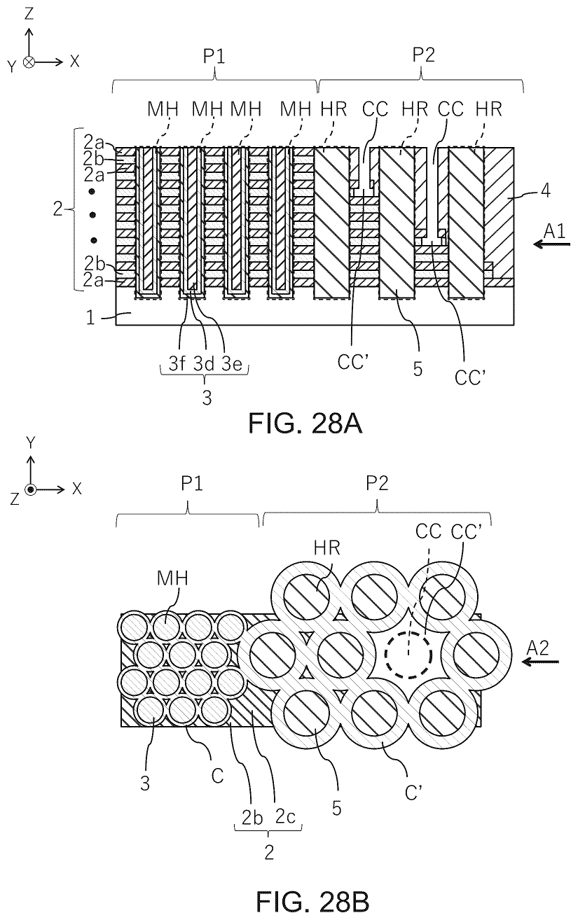

Next, the portion of the insulator 2c is removed by etching through each of the contact holes CC (FIGS. 28A and 28B). As a result, each of the expanded contact holes CC′ in the stacked film 2 is formed below one corresponding contact hole CC.

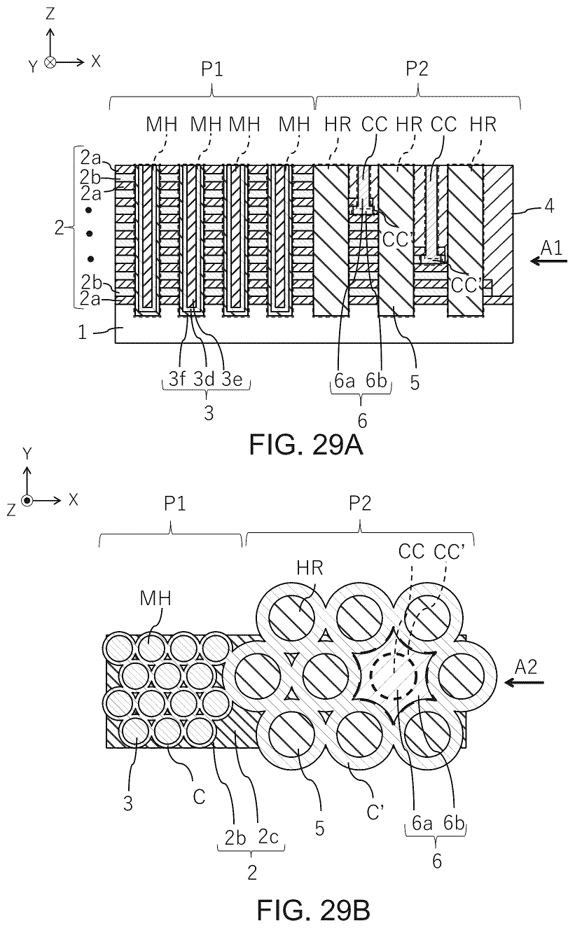

Next, the plurality of contact plugs 6 are formed in the stacked film 2 and the inter layer dielectric 4 (FIGS. 29A and 29B). The plug body 6a of each of the contact plugs 6 is formed in one corresponding contact hole CC, and the plug base 6b of each of the contact plugs 6 is formed in one corresponding expanded contact hole CC′. The plug body 6a and the plug base 6b of each of the contact plugs 6 of the present embodiment are simultaneously formed by embedding the same metal material in the corresponding contact hole CC and expanded contact hole CC′. In such a manner, the semiconductor device illustrated in FIGS. 21 and 22 is manufactured.

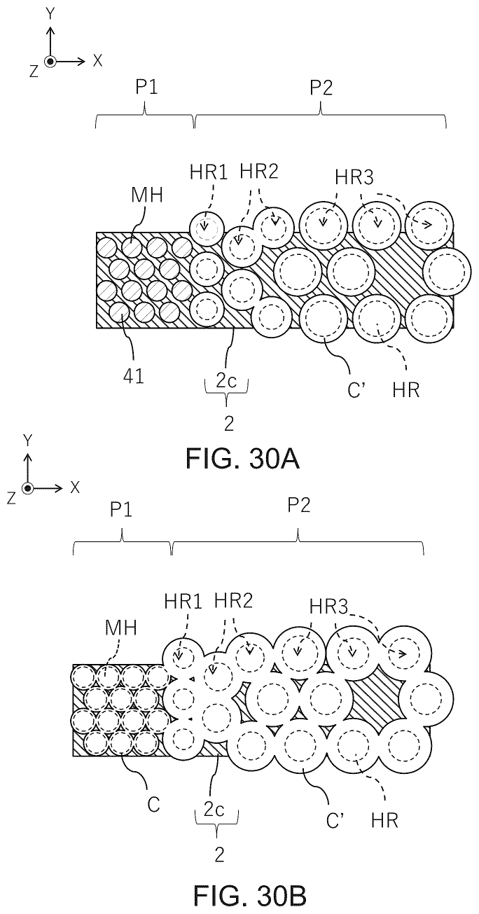

FIGS. 30A and 30B are plan views illustrating a method of manufacturing a semiconductor device of a modification of the fifth embodiment. FIGS. 30A and 30B are the plan views which correspond to FIG. 22.

A step illustrated in FIG. 30A corresponds to a step illustrated in FIGS. 24A and 24B. A plurality of holes HR illustrated in FIG. 30A include a plurality of holes HR1, a plurality of holes HR2 which have a larger diameter than a diameter of the holes HR1, and a plurality of holes HR3 which have a larger diameter than the diameter of the holes HR2. The hole HR2 is arranged at a distant position from the flat portion P1 compared to the hole HR1. The hole HR3 is arranged at a distant position from the flat portion P1 compared to the hole HR2. Accordingly, the diameters of the plurality of holes HR illustrated in FIG. 30A become larger at more distant positions from the flat portion P1.

A step illustrated in FIG. 30B corresponds to a step illustrated in FIGS. 25A and 25B. In the present modification, the diameters of the holes HR are made larger as their positions become more distant from the flat portion P1, and it thereby becomes possible to easily couple together the plurality of cavities C and C′ illustrated in FIG. 30B. Thus, when the method of manufacturing the semiconductor device of the fifth embodiment, which is illustrated in FIGS. 23A to 29B, is carried out, the steps illustrated in FIGS. 30A and 30B may be employed.

In the present embodiment, contents of the first embodiment are applied not only to the flat portion P1 but also to the stair structure portion P2, and it thereby becomes possible to form suitable electrode layer 2b, beam portion 5, contact plug 6, and so forth.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film including a plurality of first insulators and a plurality of electrode layers that are alternately provided in a first direction; and
a plurality of columnar portions extending in the first direction in the stacked film,
wherein a first columnar portion among the plurality of columnar portions includes:
a second insulator provided on side faces of the plurality of first insulators and the plurality of electrode layers, and including a metallic element;
a third insulator provided on a side face of the second insulator, and including silicon;
a charge storage layer provided on a side face of the third insulator;
a fourth insulator provided on a side face of the charge storage layer; and
a semiconductor layer provided on a side face of the fourth insulator.

2. The device of claim 1, wherein the stacked film further includes a plurality of fifth insulators that are provided alternately with the plurality of first insulators in the first direction.

3. The device of claim 2, wherein the plurality of fifth insulators are provided on side faces of the plurality of electrode layers.

4. The device of claim 2, wherein the plurality of first insulators include silicon and oxygen, and the plurality of fifth insulators include silicon and nitrogen.

5. The device of claim 2, wherein the plurality of fifth insulators include at least a fifth insulator having a first film quality, and a fifth insulator having a second film quality different from the first film quality.

6. The device of claim 2, wherein
a predetermined electrode layer among the plurality of electrode layers, and a predetermined fifth insulator among the plurality of fifth insulators are provided between a lower insulator and an upper insulator among the plurality of first insulators,
the predetermined electrode layer includes a surrounding portion that annularly surrounds the columnar portion, and
the predetermined fifth insulator includes a first portion provided in the predetermined electrode layer.

7. The device of claim 2, wherein
a predetermined electrode layer among the plurality of electrode layers, and a predetermined fifth insulator among the plurality of fifth insulators are provided between a lower insulator and an upper insulator among the plurality of first insulators, and
the predetermined electrode layer includes a first conductive layer provided on an upper face of the lower insulator, a lower face of the upper insulator, and a side face of the predetermined fifth insulator, and a second conductive layer provided on an upper face, a lower face, and a side face of the first conductive layer.

8. The device of claim 1, further comprising a sixth insulator extending in the first direction in a stair structure portion of the stacked film,
wherein a predetermined electrode layer among the plurality of electrode layers includes a surrounding portion that annularly surrounds the sixth insulator.

9. The device of claim 8, further comprising a plug provided on the stair structure portion of the stacked film, and electrically connected to the predetermined electrode layer.

10. The device of claim 9, wherein the plug includes a lower portion provided on a side face of the predetermined electrode layer, and an upper portion provided on the lower portion and extending in the first direction.

11. The device of claim 1, wherein the plurality of columnar portions are arranged in a shape of a triangular lattice in a planar view.

12. The device of claim 11, wherein the triangular lattice is formed with a plurality of equilateral triangles or a plurality of isosceles triangles.

13. The device of claim 11, wherein
the stacked film further includes a plurality of fifth insulators that are provided alternately with the plurality of first insulators in the first direction, and
a predetermined fifth insulator among the plurality of fifth insulators includes a first portion that is interposed among at least three columnar portions among the plurality of columnar portions.

14. The device of claim 13, wherein the predetermined fifth insulator among the plurality of fifth insulators further includes a second portion extending between one or more columnar portions in a first region and one or more columnar portions in a second region.

15. The device of claim 14, further comprising a third conductive layer extending in the first direction in the second portion.

16. A method of manufacturing a semiconductor device, comprising:
forming a stacked film including a plurality of first insulators and a plurality of fifth insulators that are alternately provided in a first direction;
forming a first concave portion extending in the first direction in the stacked film;
removing at least portions of the plurality of fifth insulators from the first concave portion to form a plurality of second concave portions between the plurality of first insulators;
forming a plurality of electrode layers in the plurality of second concave portions; and
forming a columnar portion in the first concave portion.

17. The method of claim 16, wherein the columnar portion is formed by:
forming a second insulator including a metallic element, on side faces of the plurality of first insulators and the plurality of electrode layers in the first concave portion;
forming a third insulator including silicon, on a side face of the second insulator;
forming a charge storage layer on a side face of the third insulator;
forming a fourth insulator on a side face of the charge storage layer; and
forming a semiconductor layer on a side face of the fourth insulator.

18. The method of claim 16, wherein the plurality of second concave portions are formed such that the portions of the plurality of fifth insulators are removed and other portions of the plurality of fifth insulators remain.

19. The method of claim 16, wherein the stacked film, the first concave portion, and the plurality of second concave portions are formed by:
forming a lower stacked film of the stacked film;
forming, in the lower stacked film, a lower portion of the first concave portion and a plurality of third concave portions among the plurality of second concave portions;
forming an upper stacked film of the stacked film on the lower stacked film; and
forming, in the upper stacked film, an upper portion of the first concave portion and a plurality of fourth concave portions among the plurality of second concave portions.

20. The method of claim 19, wherein
a first film is formed in the lower portion of the first concave portion and the plurality of third concave portions, after the plurality of third concave portions are formed in the lower stacked film, and
the first film is removed from the lower portion of the first concave portion and the plurality of third concave portions, after the upper portion of the first concave portion is formed in the upper stacked film.
